(19) United States
(12) Patent Application Publication
(10) Pub. No.: US 2016/0091682 A1
(43) Pub. Date: Mar. 31, 2016

(54) STACKABLE HYBRID NETWORK INTERFACE DEVICE

(71) Applicants: George I. WAKILEH, Batavia, IL (US); Owen B. WEIKLE, Hutchinson, MN (US); Nicholas B. LARSSON, Blomkest, MN (US); Federico ZAMORA, Hector, MN (US); Fabricio ROJAS, Hector, MN (US)

(72) Inventors: George I. Wakileh, Batavia, IL (US); Owen B. Weikle, Hutchinson, MN (US); Nicholas B. Larsson, Blomkest, MN (US); Federico Zamora, San Lorenzo de Flores (CR); Fabricio Rojas, Curridabat (CR)

(21) Appl. No.: 14/891,125

(22) PCT Filed: May 14, 2014
(86) PCT No.: PCT/US2014/037952

§ 371 Date: Nov. 13, 2015

Related U.S. Application Data
(60) Provisional application No. 61/823,252, filed on May 14, 2013.

(51) Int. Cl. G02B 6/44; H05K 5/02; H02G 3/08; H02G 3/18; G02B 6/38; H01R 25/00

(52) U.S. Cl. CPC G02B 6/4446; G02B 6/4477; G02B 6/3897; H01R 25/006; H02G 3/086; H02G 3/083; H02G 3/081; H02G 3/18; H05K 5/0226

(57) ABSTRACT

A network interface device for providing a demarcation point between a central office of a telecommunications network and the customer's premise wiring, whether a copper wire cable or a fiber optic cable. The NID includes a base unit having a back wall having a perimeter and a continuous side wall extending from the perimeter of the back wall, the continuous side wall having a first wall portion and an opposing second wall portion wherein the back wall and the continuous side wall define an interior cavity. The NID includes a cable entrance port and a cable exit port in the first wall portion where both the cable entrance port and the cable exit port include a groove in an external surface. The NID includes a first connecting port and a second connecting port within the opposing second wall portion wherein the connecting ports are configured to accept the groove in the cable entrance and exit ports. The NID includes spaced apart first and second torsion reducing elements extending from the first wall portion and spaced apart first and second torsion reducing receiving elements extending from the second wall portion and having a cavity for receiving the first and second torsion reducing elements. The NID includes a connecting device within the base unit for connecting or disconnecting a fiber optic cable or copper wire cable from the central office to the premise.

### BACKGROUND

Disclosed embodiments relate to network interface device (NID) that serves as a demarcation point between a central office of a telecommunications network and a customer's premise. More particularly the disclosed embodiments relate to a NID that provides flexibility to utilize the NID for both fiber optic cable and copper wire data transmission networks.

The NID is typically a weatherproof enclosure that is mounted on an exterior surface of a home or a multi-dwelling residence. The NID can be mounted anywhere distribution of a passive optical fiber network or a copper wire network is desired.

The telecommunications industry typically utilizes either fiber optic networks or copper wire networks to transmit data. Both fiber optic networks and copper wire networks require a separate NID, as a NID for a fiber optic network is not compatible with a copper wire network and vice versa. Therefore, it can be difficult to supply both a fiber optic network and a copper wire network to the same home or multi-dwelling residence.

Also, the NID includes a limited number of connections, which may not be sufficient for some multi-user applications. Therefore, multiple unconnected NIDs may be required to provide the necessary data network capabilities to a home or multi-dwelling residence.

While a copper wire network can be cut to a specific length, typically, a feed or drop optical fiber cable is provided to a premises, by an optical fiber service provider, from a larger distribution point or connection (e.g., a pole mounted distribution point). The feed is typically a heavy jacketed or hardened multi-fiber cable that is broken out at the premises into individual fiber connections. This is for example commonly the case at multi-dwelling residential buildings or at buildings that house multiple different businesses. Individual distribution fiber cables from inside each living or workplace unit are connected with adapters to the individual feed fiber optical cable connections from the multi-fiber drop cable.

Increasingly, optical fiber cables are pre-connectorized—that is they are shipped from a factory with terminating connectors already installed. This can lead to the need for installers to deal with excess optical fiber cable length in many instances. Other factors can also result in excess cable length. Storage of the excess cable length can be problematic, as can organization of the drop optical fiber cable, the multiple individual feed optical fiber cables, and the multiple individual distribution optical fiber cables which are connected to the individual living or workplace units. The fact that the various optical fiber cables are pre-connectorized provides other challenges when attempting to store or organize the cables. Also, there is a need to protect the optical fiber cables from excessive strain, as well as from damage due to bending the cables at too small of a bend radius.

The discussion above is merely provided for general background information and is not intended to be used as an aid in determining the scope of the claimed subject matter.

### SUMMARY

Disclosed are exemplary embodiments of a network interface device (NID) for providing a demarcation point between a central office of a telecommunications network and the customer's premise wiring, whether a copper wire cable or a fiber optic cable. The NID includes a base unit having a back wall having a perimeter and a continuous side wall extending from the perimeter of the back wall, the continuous side wall having a first wall portion and an opposing second wall portion wherein the back wall and the continuous side wall define an interior cavity. The NID includes a cable entrance port and a cable exit port in the first wall portion where both the cable entrance port and the cable exit port include a groove in an external surface. The NID includes a first connecting port and a second connecting port within the opposing second wall portion wherein the connecting ports are configured to accept the entrance and exit ports by accepting the groove. The NID includes spaced apart first and second torsion reducing elements extending from the first wall portion and spaced apart first and second torsion reducing receiving elements extending from the second wall portion and having a cavity for receiving the first and second torsion reducing elements. The torsion reducing elements and the torsion reducing receiving elements are configured to cooperate to prevent a torsional force from being placed on the connection of the cable entrance port and the cable exit port with the first and second connecting ports, respectively. A cover is hingedly attached to the base unit to selectively enclose a storage area provided in the base unit. The NID includes a connecting device within the base unit for connecting or disconnecting a fiber optic cable or copper wire cable from the central office to the premise.

Exemplary embodiments include at least two NIDs for providing a demarcation point between a premise and a central office of a telecommunications network for either a copper wire cable or a fiber optic cable. Each NID comprises a base unit comprising a back wall having a perimeter and a continuous side wall extending from the perimeter of the back wall, the continuous side wall having a first wall portion and an opposing second wall portion wherein the back wall and the continuous side wall define an interior cavity. The NID includes a cable entrance port and a cable exit port in the first wall portion wherein the cable entrance port and the cable exit port both have an outer surface comprising a groove. The NID includes a first connecting port and a second connecting port within the opposing second wall portion wherein the connecting ports are configured to accept the entrance and exit ports by accepting the groove. The NID includes spaced apart first and second torsion reducing elements extending from the first wall portion and spaced apart first and second torsion reducing receiving elements extending from the second wall portion and having a cavity for receiving the first and second torsion reducing elements, wherein the torsion reducing elements and the torsion reducing receiving elements are configured to cooperate to prevent a torsional force from being placed on the connection of the cable entrance port and the cable exit port with the first and second connecting ports, respectively. A cover is hingedly attached to the base unit to selectively enclose a storage area provided in the base unit. The NID includes a connecting device within the base unit for connecting or disconnecting a fiber optic cable or copper wire cable from the central office to the premise. To connect the at least two NIDS together the grooves of the cable entrance port and the cable exit ports of one network interface device are positioned about the first and second connecting ports of a second network interface device and the first and second torsion reducing elements of the first network interface device are positioned within the first and second torsion reducing receiving elements.

Exemplary embodiments of the NID include providing a demarcation point between a premise and a central office of a telecommunications network a fiber optic cable. The network interface device comprises a base unit comprising a back wall having a perimeter and a continuous side wall extending from the perimeter of the back wall, the continuous side wall having a first wall portion and an opposing second wall portion wherein the back wall and the continuous side wall define an interior cavity. The NID includes a cable entrance port and a cable exit port in the first wall portion. The NID includes a bulkhead connector attached to the back wall. The bulkhead connector comprises a plurality of first receptacles, wherein each of the plurality of first receptacles is configured to accept a connector attached to an end of a fiber optic cable from the central office, and a plurality of second receptacles, wherein each of the plurality of second receptacles with one of the receptacles of the plurality of first receptacles, wherein each of the plurality of second receptacles is configured to accept a connector attached to an end of the fiber optic cable to the premise. The NID includes a carrier having a wall with a first side and a second side and an aperture therethrough where the carrier is slidably attached to the back wall. An adapter is supported by the first side of the back wall, the adapter having first and second ports are configured to accept a prefabricated connector the first and second ports being substantially perpendicular to the bulkhead connector. The NID includes a cover having a hinged connection to the base unit to selectively enclose a storage area provided in the base unit.

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a diagrammatic illustration of the use of a network interface device in accordance with disclosed embodiments.

FIG. 2 is partial exploded view of a network interface device compatible with a fiber optic network.

FIG. 3 a perspective view of a network interface device compatible with a copper wire network.

FIG. 4 a perspective view of a mounting plate for a network interface device compatible with a copper wire network.

FIG. 5 is a perspective view of two network interface devices connected together.

FIG. 6 is an exploded view of a port plate removed from a connector port of a network interface device.

FIG. 7 is a partial perspective view of an entrance or exit port of the network interface device.

FIG. 8 is a partial perspective view of an entrance or exit port of one network interface device engaging a connector port of another network interface device.

FIG. 9 is a partial perspective view of the entrance and exit ports of a first network interface device being positioned into connector ports of a second network interface device.

FIG. 10 is a partial perspective view of another embodiment of the network interface device where the two network interfaces devices are connected together.

FIG. 11 is a partial perspective view of the other embodiment of the network interface device where the two network interfaces devices are partially connected together.

FIG. 12 is a partial perspective view of a connecting device for two adjacent NIDs.

FIG. 13 is a partial perspective view of a connecting device for two adjacent NIDs partially connected together.

FIG. 14 is a partial perspective view of a connecting device for two adjacent NIDs in a disconnected configuration.

FIG. 15 is a partial perspective view of another network interface device.

FIG. 16 is another partial perspective view of the network interface device.

FIG. 17 is a partial top view of the network interface device of FIGS. 15 and 16.

FIG. 18 is another partial perspective view of the network interface device.

FIG. 19 is another partial perspective view of the network interface device where an inner cover is in a closed position that provides a craft separation within the network interface device between the splice side and the installation side of the network interface device.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Disclosed embodiments include a network interface device (NID) which allows for the connection of multiple NIDs together in an arrangement sealed from the weather. The disclosed embodiments also allows for the demarcation of both copper wire networks and fiber optic networks from a central office and a customer's premise.

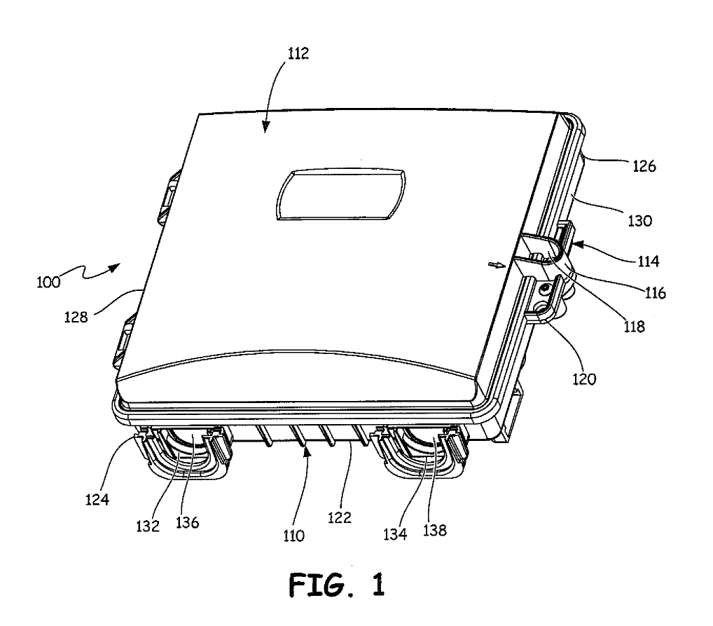

Referring now to FIG. 1, shown is a diagrammatic illustration of the NID 100 in accordance with exemplary embodiments. NID 100 mounts at a desired location of a premise, which will typically be a home, multi-dwelling or multi-business type of premises in which multiple individual living spaces or units are included in a single larger building. However, NID 100 is not limited to use in this type of premises.

NID 100 includes a base unit 110 and a door or cover 112 which has a hinged connection to the base unit 110. A latch 114 secures cover 112 to base unit 110 in a closed position, and a security screw housing 116 is formed with or in cover 112 and is configured to receive a security screw 118 for denying entry into NID 100 to persons without a proper tool. When in a closed position, base unit 110 and cover 112 form a weather-proof seal that prevents moisture from entering an interior space of NID.

For further security, a padlock hasp 120 is also included in an exemplary embodiment for receiving a padlock (not shown) to lock cover 112 to base unit 110 in a closed position. In one exemplary embodiment, padlock hasp 120 can be integrally formed with the material of cover 112 and base unit 110. For example, in an exemplary embodiment cover 112, base unit 110 and the above-described components (not including security screw 118) are formed of a plastic material. In other embodiments, hasp 120 and/or other components are formed of other materials (e.g., metals) which are attached to cover 112 and/or base unit 110.

NID 100 includes back wall 122. Extending from a perimeter of the back wall 122 are a bottom wall 124, a top wall 126, a left wall 128 and a right wall 130 where the walls 124-130 are connected together to from a continuous perimeter. The bottom wall 124 includes a cable entrance port 132 and a cable exit port 134 where the ports 132 and 134 are capable of receiving either a copper wire cable or a fiber optic cable. When cables are not inserted through the ports 132 and 134, cable port grommet 136 and 138 are secured within the ports 132 and 134, respectively, to seal the ports 132 and 134 to prevent moisture, dirt and/or debris from entering the interior cavity of NID.

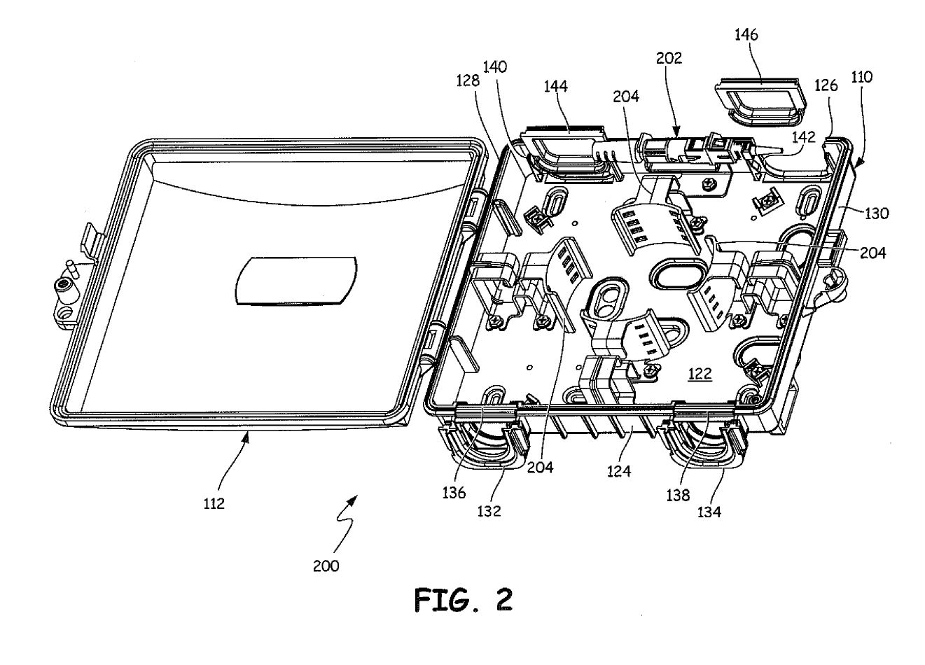

Referring to FIG. 2, a perspective view of a NID 200 for a fiber optic cable is illustrated. In this application like features in different embodiments will be given like reference characters. In FIG. 2, the NID 200 is illustrated with the cover 112 in an open position relative to the base unit 110 to show the interior of the NID.

The NID 200 includes the cable entrance port 132 with a cable port grommet 136 secured therein and a cable exit port 134 with a cable port grommet 138 secured therein. The NID 200 includes an adapter 202 positioned proximate the top wall 126 that includes a receptacle configured to accept a prefabricated connector, such as, but not limited to a SC connector. The adapter 202 includes a second receptacle that is configured to accept another connector such as, but not limited to, an SC connector. The adapter 202 thereby allows a fiber optic cable can be connected and/or disconnected therefrom to complete or disconnect the fiber optic service to the premise.

Extending from the back wall 122 are a plurality of arcuate storage clips 204 that act as a reel for storing excess length of prefabricated cable. As the fiber optic cables are typically prefabricated at a factory and include a selected connector, the storage clips 204 allow the excess length to be stored without harming the relatively rigid fiber optic cable.

The top wall 126 includes left and right connecting ports 140 and 142 that can optionally accept left and right port plates 144 and 146, respectively. The port plates 144 and 146 prevent moisture, dirt and debris from entering the interior of the NID 200 when not used in a stackable configuration.

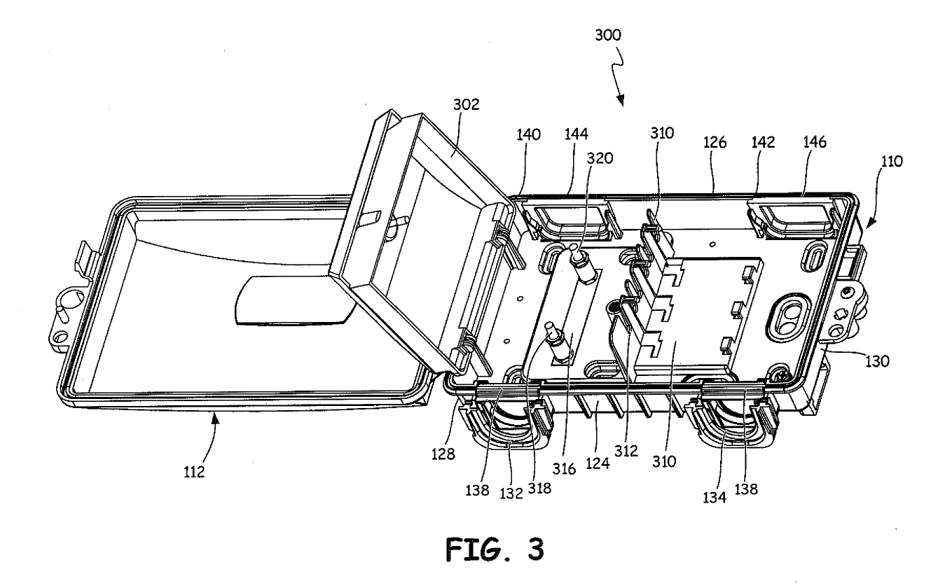

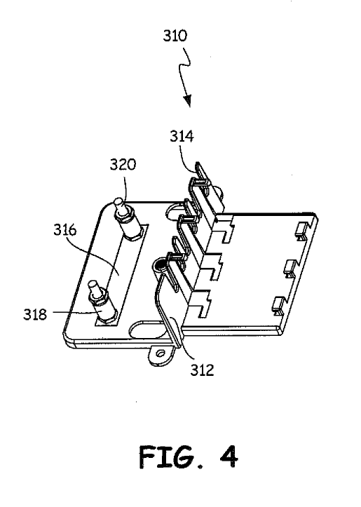

Referring to FIGS. 3 and 4, a NID 300 compatible with a copper wire cable is illustrated. The NID 300 performs a similar function as that of the NID 200, but for a cable wire network by using a NID copper-use insert 310.

The NID 300 includes an interior cover 302 hingedly attached to the base unit 110 that is accessible by the network provider. With the interior cover 302 in the open position, the NID copper-use insert 310 is accessible. The NID copper-use insert 310 includes a partition 312 that includes a plurality of V shaped notches 314 that are in a pairs where each pair of wires are inserted into the V shaped notches 314 to allow the wires to pass from one side to the other.

The NID mounting plate 310 also includes a ground bar 316 that includes ground connections 318 and 320 for the service provider. The ground bar 316 may be molded to the mounting plate 310, however, the ground bar 316 may also be secured to the mounting plate 310 by other securing mechanisms.

As shown in FIGS. 1-3, the substantially same NID 100, 200, 300 can be utilized to provide a demarcation point between a network provider and a premise. The difference being the connecting mechanisms 202 and 204 for the fiber optic cable and the NID copper-use insert 310 for the copper wire cable networks, respectively.

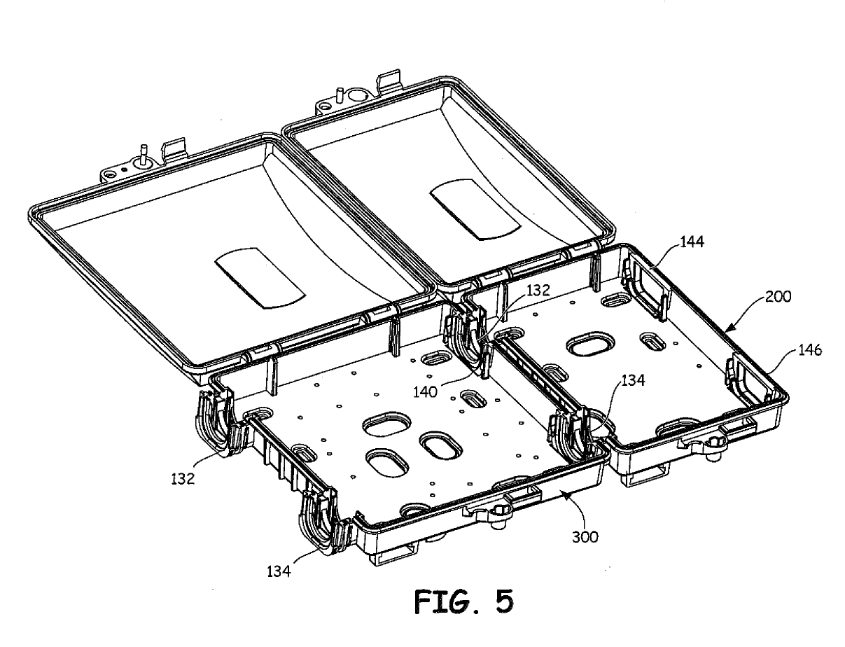

Besides being able to accept either fiber optic cables or copper wire cables, the NIDs 100, 200 and 300 are stackable onto another to provide greater flexibility and provide greater capabilities at a single location. Referring to FIG. 5, the NID 200 is illustrated connected to the NID 300.

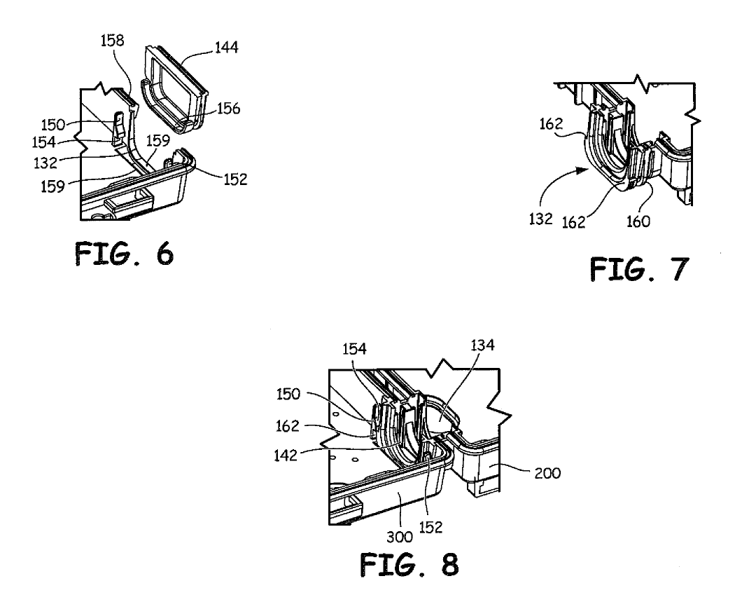

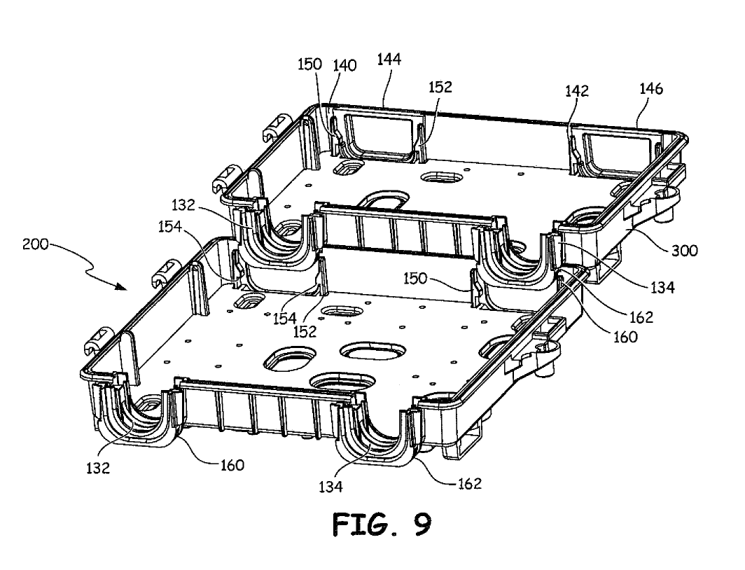

Referring to FIGS. 5-9, the NIDs 200 and 300 are illustrated connected and in the process of being connected along with the connecting mechanisms. To stack the NID 200 to the NID 300, the port plates 144 and 146 are removed from the connecting ports 140 and 142. The port plates 144 and 146 are removed by depressing left and right latch tabs 150 and 152 which causes a latching surface 154, which is substantially flat, to disengage a flat surface 156 on the port plate 144 and 146. With the flat latching surface 154 disengaged from the flat surface 156, the port plates 144 and 146 can be removed from the connecting ports 140 and 142 and thereby expose a beveled retaining flange 159 that has a narrower width at the top edge 158 that increases in width toward a bottom edge 159 of the connecting port 140 and 142. The flange 159 extends along the bottom surface of the port 140 and 142 and upwardly to a top edge of both side surfaces of the connecting port 140 and 142.

To connect two NIDs 200 to 300, 300 to 300, or 200 to 200, with the plates 144 and 146 removed from the connecting ports 140 and 142, the entrance port 132 and the exit port 134 are positioned above the connecting port 140 and 142, respectively. Both the entrance port 132 and the exit port 134 include alignment grooves 160 that are the same configuration. The grooves 160 are configured to engage the retaining flange 159 of the respective connecting port 140 and 142. The entrance port 132 and the exit port 134 are forced downwardly and into the connecting ports 140 and 142, respectively, such that the flat latching surfaces 154 engage the flat shoulders 162.

Therefore, any number of NIDS 100, 200, 300 can be secured to each other in the same manner where the entrance and exit ports 132 and 134 are secured into the connecting ports 140 and 142 of the adjacent NID and secured thereto utilizing the latches 154 engaging the flat shoulders 162. The NIDs can be separated by manipulating the latches 154 to disengage the flat shoulders 162 and therefore allow the NID 200 to be disconnected from the adjacent NID 300.

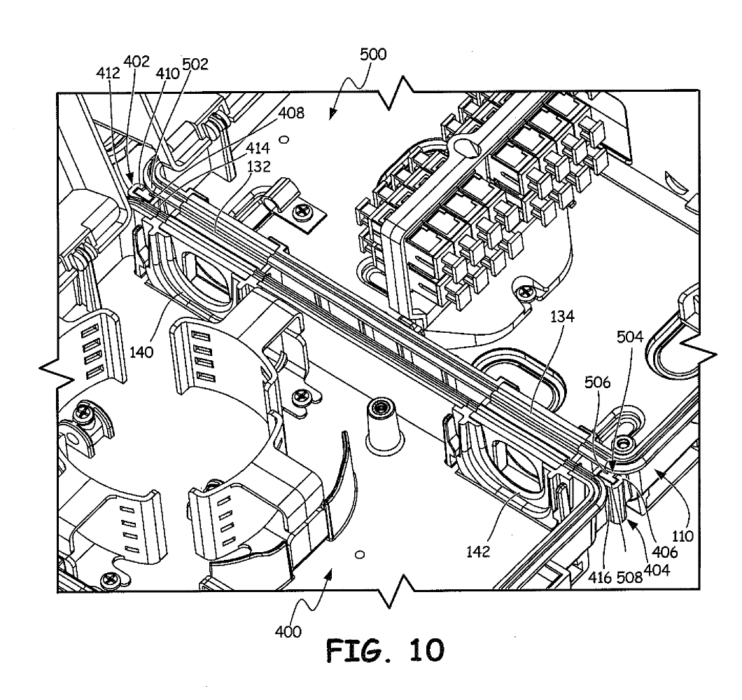

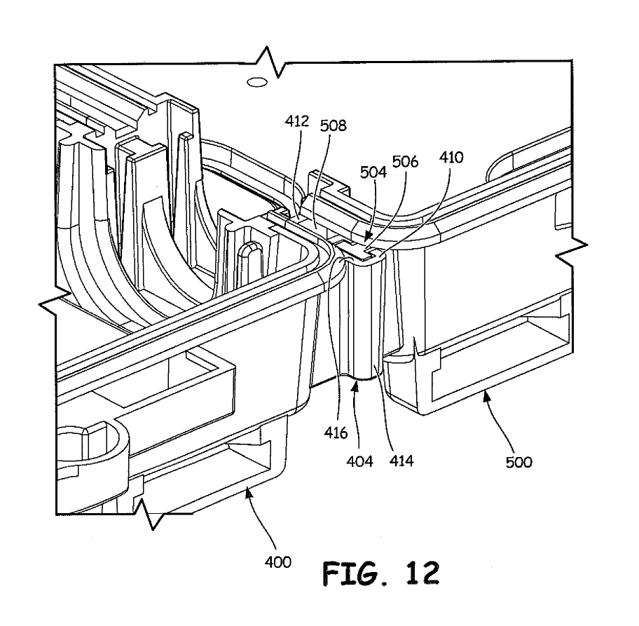

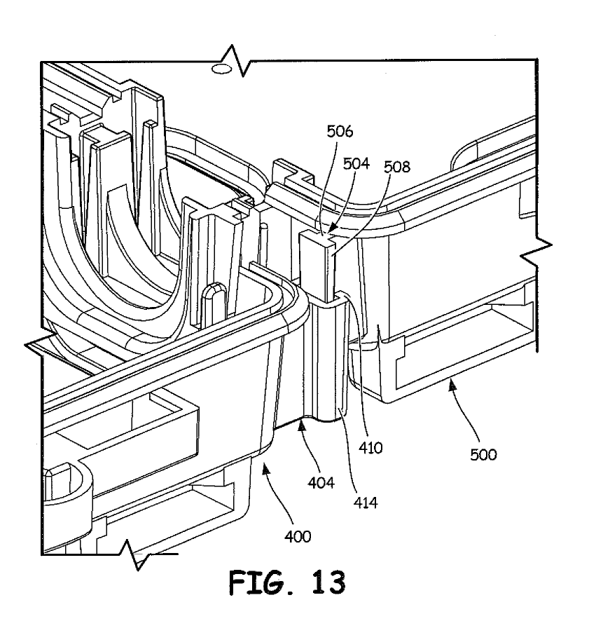

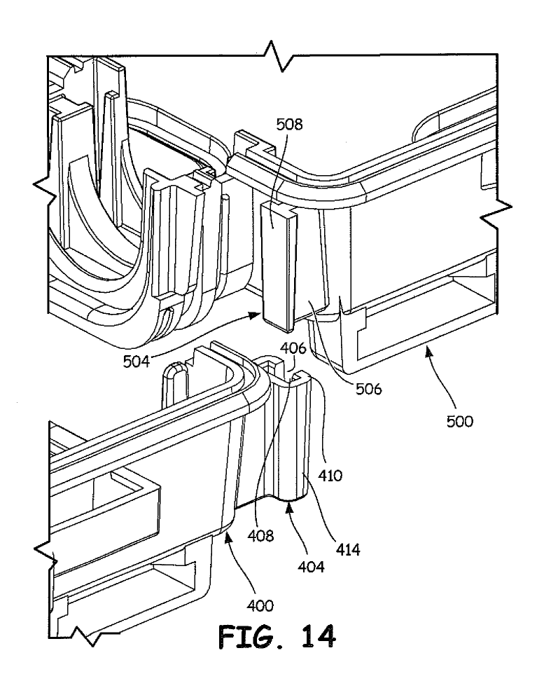

Referring to FIGS. 10-14, NIDs 400 and 500 are illustrated. The NID 400 has a similar construction that of NID 200 and the NID 500 has a similar construction to that of NID 300. Similar features in NID 400 will be given the same reference characters as used with NID 200 and similar features in NID 500 will be given similar reference characters as used with NID 300.

The NID 400 includes left and right channels 402 and 404. Each channel 402 and 404 includes an entrance slot 406 in a top wall 408 that provides access to an internal cavity 410. The internal cavity is defined by the top wall 408, left and right side walls 412 and 414, and a bottom wall 416 that extends substantially along a height of the base unit 110.

The NID 500 includes left and right extensions 502 and 504, each having a substantially vertical member 506 extending from the bottom wall 124. Substantially horizontal end members 508 extend from the substantially vertical member 506. The substantially horizontal member 508 and the substantially vertical member 506 have a complementary configuration to that of the internal cavity 410 and the entrance slot, and extend substantially a height of the base unit 110. As the NID 400 is connected to the NID 500, the entrance port 132 and the exit port 134 are forced downwardly and into the connecting ports 140 and 142, respectively, until the flat latching surfaces 154 engage the flat shoulders 162.

Also, the substantially horizontal member 508 is positioned with the internal cavity and the substantially vertical member 506 is positioned through the entrance slot 406. The interaction of the substantially vertical member 506 with the top wall 408 and the interaction with of the substantially horizontal member 508 with the walls 408, 412, 414 and 416 provide additional rigidity to the connection of the NIDs 400 and 500 and also prevent a torque from disconnecting the ports 132 and 140 and the ports 134 and 142, all respectively. Therefore, the additional interconnections of the left and right channels 402 and 404 with the extensions 502 and 504, provides a more robust connection between the NIDs 400 and 500 that is able to withstand forces, such as torque forces.

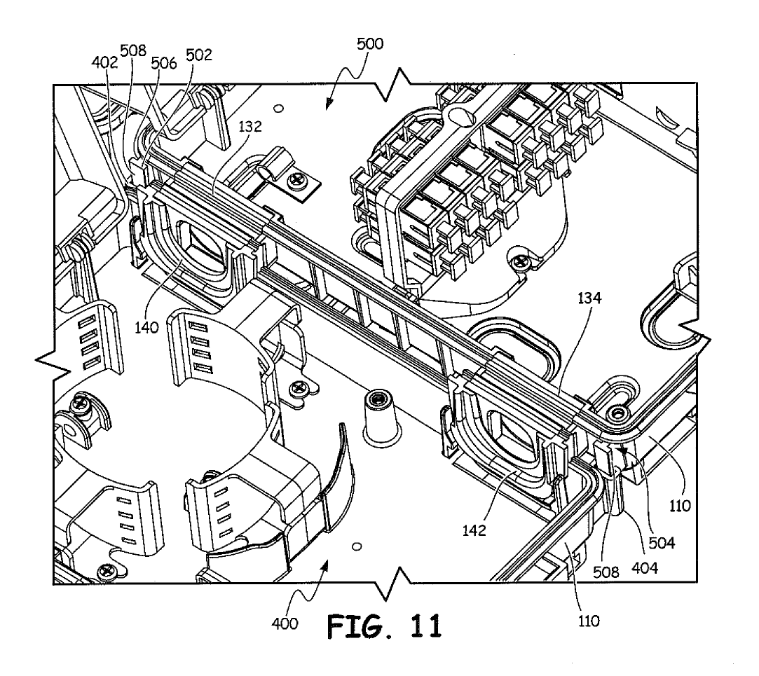

While FIGS. 10 and 11 disclose NIDs 400 and 500 being connected together with the ports 132 and 140 and the ports 134 and 142 and the left and right channels 402 and 404 with the extensions 502 and 504, two or more NIDs 400 can be connected together utilizing the same interconnection. Similarly two or more NIDs 500 can be connected together utilizing the same interconnection.

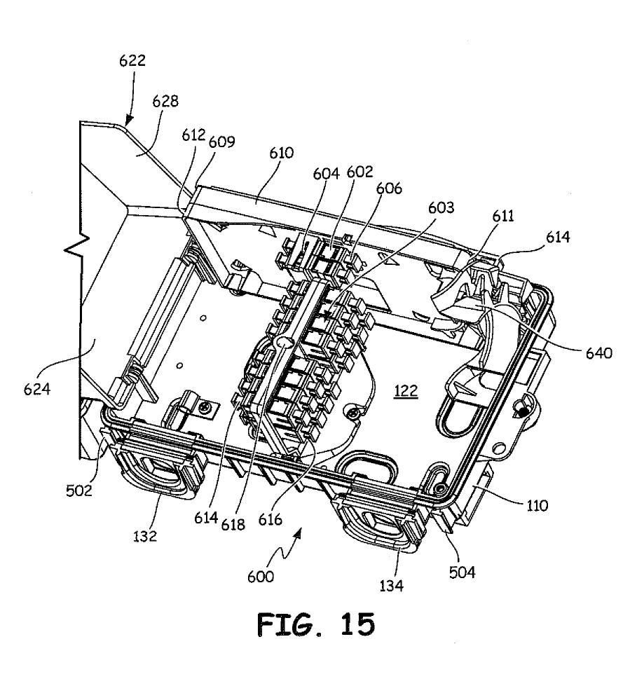

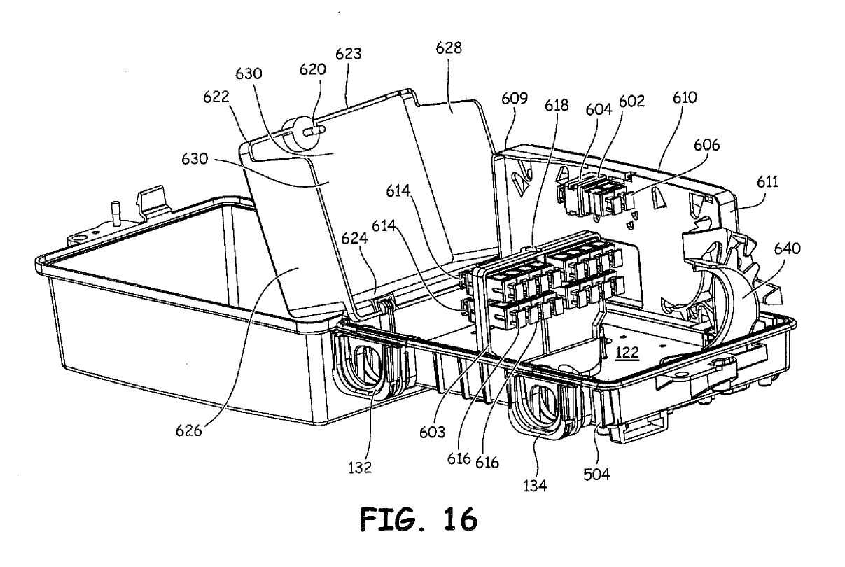

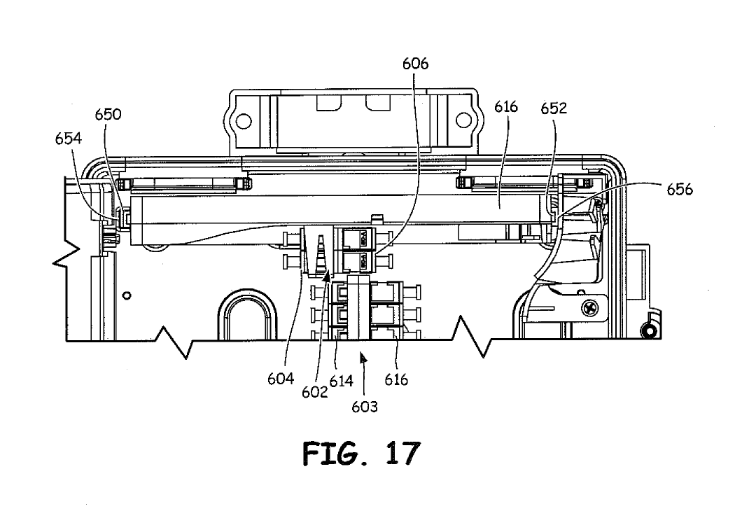

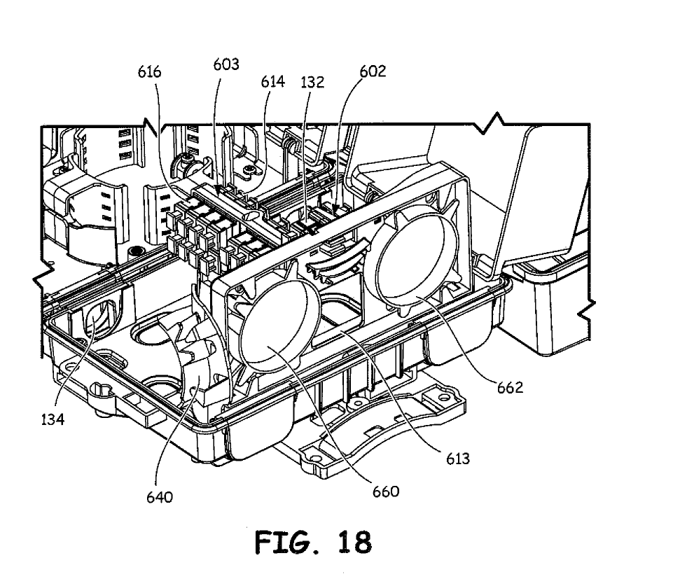

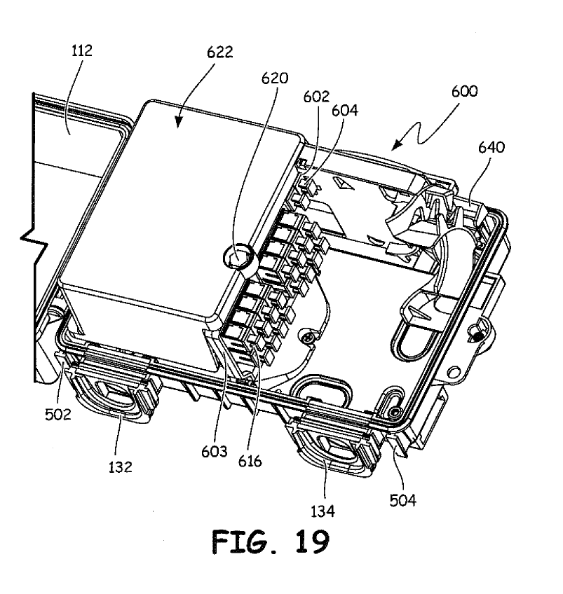

Referring to FIGS. 15-18, another NID 600 is illustrated. The NID includes a base unit 110 with similar exterior elements as discussed with respect to NIDs 400 and 500 includes the interconnecting ports 132 and 140 and the ports 134 and 142 and the left and right channels 402 and 404 with the extensions 502 and 504.

The NID 600 includes an adapter 602 and a bulkhead connector 603 for a fiber optic network. The bulkhead connector 603 is attached to the back wall 122 and includes a series of left and right receptacles 614 and 616 respectively. Opposing pairs of the receptacles 614 and 616 are in communication with each other and connect the provider network to the premise network.

The adapter 602 is attached to a carrier 610, where the carrier 610 includes left and right ribs 650 and 652 on left and right side walls 609 and 611. The left and right ribs 650 and 652 slidably engage left and right channels 654 and 656 extending from the back wall 122. The slidable engagement of the left and right ribs 650 and 652 with the left and right channels 654 and 656 allow the carrier 610 to be moved outwardly from the back wall 122 to provide access to the fiber optic ports 604 and 606 on an adapter and one or more splitters (not shown) located on the carrier 610. The ability to move the carrier 610 outwardly from the back wall 122 allows the ports 604 and 606 and the splitter ports to be cleaned with a tool in the event that dirt or debris enters the ports 604 and 606 or the splitter ports.

The ports 604 and 606 are adapted to accept a prefabricated connector, such as, but not limited to, a SC connector and can be oriented substantially perpendicular to the bulkhead connector 603. A fiber optic cable from the provider is inserted through port 132 and the ends are inserted into ports 604 on the adapter 602. Ends of additional fiber optic cables, is positioned through aperture 613 of the carrier 610 where the ends are inserted into ports 606 of the adapter 602. The adapter 602 therefore connects the fiber optic cable from the provider to the cables inserted through the aperture 613.

Excessive lengths of the cables are wound about reels 660 and 662 located on a back wall of the carrier 610. The reels 660 and 662 retain the slack fiber optic cable while providing a bend radius limit that prevents the fiber optic cable from breaking or becoming damaged through excessive bending. It should be noted that the carrier 610 typically includes a back cover, which is not illustrated in FIGS. 15-18 so that the components in the back of the carrier 610 can be illustrated.

The ends of the cables on the reels 660 and 662 are then connected to separate splitters, which are not illustrated. The splitters are typically passive optical splitters that split the signal at a predetermined ratio. In this instance the splitters are 1:8 splitters. However, one or more splitters with a selected splitting ratio are also contemplated besides two splitters with a 1:8 ratio.

The split signal is carried through cables from the splitters, through the aperture 613 and to the ports 614 on the provider side of the bulkhead connector 603. Dust caps are removed to provide access to the ports 614, and in this instance sixteen (16) fiber optic cable connections can be inserted into the ports. However, more or less than sixteen (16) fiber optic ports are also contemplated.

Fiber optic cables to the premise is positioned through the port 134. The NID 600 also includes a partial reel 640 that allows lengths of fiber optic cables to the premise to be placed about the reel 640 to manage the length of the cable and to securely retain the cable within the NID 600 such that the prefabricated end of the cable can be utilized. The reel 640 also limits the bend radius of the fiber optic cable to prevent the fiber optic cable from being damaged through excessive bending. The reel 640 can be located on either side of the bulkhead connector 603 or both sides of the bulkhead connector 603 depending upon the application for which the NID 600 is utilized. The reel 640 includes the right most rail of a carrier slide.

The ends of the premise fiber optic cables are then inserted into the ports 616 and make a connection with the fiber optic cable network from the provider in ports 614. Through the connection between the ports 614 and 616, the fiber optic network from the provider is connected to the premise while also provide a demarcation point between the provider network and the premise at the bulkhead connector 603.

The bulkhead connector 603 includes a cavity 618 at a midplane that accepts a security screw 620 attached to an interior security cover 622 that is hingedly attached to the base unit 110. The interior cover 622 is sized to have a distal edge 623 that is positioned along a midplane of the bulkhead connector 603 and the carrier 602 such that one side of the NID 600 can be securely isolated from the other side of the NID 600. Securely isolating one side from the other side of the NID provides for what is referred to as craft separation, meaning the work done by the craft of the premise can be isolated from the work done by the provider and vice versa.

The interior cover 622 includes a back wall 624 and left and right side walls 626 and 628 that extend from edges of the back wall 624. A cover plate 630 spans a perimeter of an upper edge of the back wall 624, the left side wall 626 and the right side wall 628. When the cover plate 630 abuts the bulkhead connector 603, a security screw 620 is manipulated to engage the cavity 618 and thereby isolate the left side of the NID 600 from the right side of the NID 600.

The interior cover 622 when secured to the bulkhead connector 603 with the security screw 620 also provides a retention mechanism for retaining the sliding wall portion 610 and therefore the carrier connector 602 in the selected position. Also, securing the bulkhead connector 603 to the interior cover 622 also provides rigidity to the bulkhead connector 603.

Once the work has been completed within the NID 600, the cover 112 is positioned into the closed position and is secured therein as previously discussed. Therefore, the NID 600 provides additional flexibility, ease of installation and security between the crafts.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. For example, in various embodiments, the NID can be made from materials other than plastic. Further, the various components can be arranged in different ways than those specifically illustrated. Other examples of modifications of the disclosed concepts are also possible, without departing from the scope of the disclosed concepts.

What is claimed is:

1. A network interface device for providing a demarcation point between a premise and a central office of a telecommunications network for either a copper wire cable or a fiber optic cable, the network interface device comprising:
a base unit comprising:
a back wall having a perimeter;
a continuous side wall extending from the perimeter of the back wall, the continuous side wall having a first wall portion and an opposing second wall portion wherein the back wall and the continuous side wall define an interior cavity;
a cable entrance port in the first wall portion;
a cable exit port in a first wall portion and spaced from the cable entrance port wherein the cable entrance port and the cable exit port both have an outer surface comprising a groove;
a first connecting port within the opposing second wall portion;
a second connecting port within the opposing second wall portion and spaced from the first connecting port wherein the connecting ports are configured to accept the entrance and exit ports by accepting the groove;
spaced apart first and second torsion reducing elements extending from the first wall portion; and
spaced apart first and second torsion reducing receiving elements extending from the second wall portion and having a cavity for receiving the first and second torsion reducing elements, wherein the torsion reducing elements and the torsion reducing receiving elements are configured to cooperate to prevent a torsional force from being placed on the connection of the cable entrance port and the cable exit port with the first and second connecting ports, respectively;
a cover having a hinged connection to the base unit to selectively enclose a storage area provided in the base unit; and
a connecting device within the base unit for connecting or disconnecting a fiber optic cable or copper wire cable from the central office to the premise.

2. The network interface device of claim 1 and wherein the cable entrance port and the cable exit port both comprise at least one flat surface on the exterior surface.

3. The network interface device of claim 2 and further comprising at least one latch attached to the back wall proximate both the first and second connecting ports where in the at least one latch is configured to engage the at least one flat surface on the exterior surface of the cable entrance port and the cable exit port.

4. The network interface device of claim 1 and wherein the connecting device comprises:
a partition attached to the back wall and wherein the partition includes a plurality of pairs of notches configured to pass wires therethrough; and
a ground bar attached to the back wall wherein the ground bar comprises at least one ground connections.

5. The network interface device of claim 1 and wherein the connecting device comprises an adapter for fiber optic cable network wherein the adapter comprises:
at least one first receptacle configured to accept a connector attached to an end of a fiber optic cable from the central office; and
at least one second receptacle in communication with the at least one first receptacle, wherein the at least one second receptacle is configured to accept a connector attached to an end of the fiber optic cable to the premise.

6. The network interface device of claim 1 wherein the connecting device comprises a bulkhead connector attached to the back wall, the bulkhead connector comprises:
a plurality of first receptacles, wherein each of the plurality of first receptacles is configured to accept a connector attached to an end of a fiber optic cable from the central office; and
a plurality of second receptacle, wherein each of the plurality of second receptacles with one of the receptacles of the plurality of first receptacles, wherein each of the plurality of second receptacles is configured to accept a connector attached to an end of the fiber optic cable to the premise.

7. The network interface device of claim 6 and further comprising an adapter supported by the back wall, the adapter having first and second ports are configured to accept a prefabricated connector the first and second ports are substantially perpendicular to the bulkhead connector.

8. The network interfaced device of claim 6 and further comprising:
a carrier having a wall with a first side and a second side and an aperture therethrough, the carrier slidably attached to the back wall;
an adapter supported by the back wall, the adapter having first and second ports are configured to accept a prefabricated connector the first and second ports are substantially perpendicular to the bulkhead connector;
at least one optical splitter attached to the second side of the wall; and
at least one reel attached to the second side of the wall, the reel configured to store excess fiber optic cable thereon.

9. In combination, at least two network interface devices for providing a demarcation point between a premise and a central office of a telecommunications network for either a copper wire cable or a fiber optic cable, wherein each of the at least two network interface devices comprises:
a base unit comprising:
a back wall having a perimeter;
a continuous side wall extending from the perimeter of the back wall, the continuous side wall having a first wall portion and an opposing second wall portion wherein the back wall and the continuous side wall define an interior cavity;
a cable entrance port in the first wall portion;
a cable exit port in a first wall portion and spaced from the cable entrance port wherein the cable entrance port and the cable exit port both have an outer surface comprising a groove;
a first connecting port within the opposing second wall portion;
a second connecting port within the opposing second wall portion and spaced from the first connecting port wherein the connecting ports are configured to accept the entrance and exit ports by accepting the groove;
spaced apart first and second torsion reducing elements extending from the first wall portion; and
spaced apart first and second torsion reducing receiving elements extending from the second wall portion and having a cavity for receiving the first and second torsion reducing elements, wherein the torsion reducing elements and the torsion reducing receiving elements are configured to cooperate to prevent a torsional force from being placed on the connection of the cable entrance port and the cable exit port with the first and second connecting ports, respectively;
a cover having a hinged connection to the base unit to selectively enclose a storage area provided in the base unit;
a connecting device within the base unit for connecting or disconnecting a fiber optic cable or copper wire cable from the central office to the premise; and
wherein the grooves of the cable entrance port and the cable exit ports of one network interface device are positioned about the first and second connecting ports of a second network interface device and the first and second torsion reducing elements of the first network interface device are positioned within the first and second torsion reducing receiving elements to connect the two network interface devices together.

10. The network interface device of claim 9 and wherein one of the connecting devices comprises:
a partition attached to the back wall and wherein the partition includes a plurality of pairs of notches configured to pass wires therethrough; and
a ground bar attached to the back wall wherein the ground bar comprises at least one ground connections.

11. The network interface device of claim 9 and wherein one of the connecting devices comprises an adapter for fiber optic cable network wherein the adapter comprises:
at least one first receptacle configured to accept a connector attached to an end of a fiber optic cable from the central office; and
at least one second receptacle in communication with the at least one first receptacle, wherein the at least one second receptacle is configured to accept a connector attached to an end of the fiber optic cable to the premise.

12. The network interface device of claim 9 wherein one of the connecting devices comprises a bulkhead connector attached to the back wall, the bulkhead connector comprises:
a plurality of first receptacles, wherein each of the plurality of first receptacles is configured to accept a connector attached to an end of a fiber optic cable from the central office; and
a plurality of second receptacles, wherein each of the plurality of second receptacles with one of the receptacles of the plurality of first receptacles, wherein each of the plurality of second receptacles is configured to accept a connector attached to an end of the fiber optic cable to the premise.

13. The network interface device of claim 12 and further comprising an adapter supported by the back wall, the adapter having first and second ports are configured to accept a prefabricated connector the first and second ports are substantially perpendicular to the bulkhead connector.

14. The network interfaced device of claim 12 and further comprising:
a carrier having a wall with a first side and a second side and an aperture therethrough, the carrier slidably attached to the back wall;
an adapter supported by the back wall, the adapter having first and second ports are configured to accept a prefabricated connector the first and second ports being substantially perpendicular to the bulkhead connector;
at least one optical splitter attached to the second side of the wall; and
at least one reel attached to the second side of the wall, the reel configured to store excess fiber optic cable thereon.

15. A network interface device for providing a demarcation point between a premise and a central office of a telecommunications network for a fiber optic cable, the network interface device comprising:
a base unit comprising:
a back wall having a perimeter;
a continuous side wall extending from the perimeter of the back wall, the continuous side wall having a first wall portion and an opposing second wall portion wherein the back wall and the continuous side wall define an interior cavity;
a cable entrance port in the first wall portion;
a cable exit port in a first wall portion and spaced from the cable entrance port;
a bulkhead connector attached to the back wall, the bulkhead connector comprises:
a plurality of first receptacles, wherein each of the plurality of first receptacles is configured to accept a connector attached to an end of a fiber optic cable from the central office; and
a plurality of second receptacles, wherein each of the plurality of second receptacles with one of the receptacles of the plurality of first receptacles, wherein each of the plurality of second receptacles is configured to accept a connector attached to an end of the fiber optic cable to the premise; and
a carrier having a wall with a first side and a second side and an aperture therethrough, the carrier slidably attached to the back wall;
an adapter supported by the first side of the back wall, the adapter having first and second ports are configured to accept a prefabricated connector the first and second ports being substantially perpendicular to the bulkhead connector; and
a cover having a hinged connection to the base unit to selectively enclose a storage area provided in the base unit.

16. The network interface device of claim 15 and further comprising:
at least one optical splitter attached to the second side of the wall; and
at least one reel attached to the second side of the wall, the reel configured to store excess fiber optic cable thereon.

17. The network interface device of claim 15 and further comprising:
a cavity in the bulkhead connector located between the plurality of first receptacles and the plurality of second receptacles;
an interior cover hingedly attached to the base unit the interior cover having a length that covers the plurality of first receptacles and having a through bore that aligns with the cavity; and
a connecting device configured to be positioned through the through bore and engaging the cavity to secure the cover to the bulkhead connector.

18. The network interface device of claim 15 and further comprising a reel attached to back wall, the reel configured to retain excess fiber optic cable from the premise.
